(19) United States
(12) Patent Application Publication
(10) Pub. No.: US 2009/0251119 A1
(43) Pub. Date: Oct. 8, 2009

(54) Three chip package

(76) Inventors: Goran Stojcic, Redondo Beach, CA (US); Primitivo A. Palasi, Baguio (PH)

Correspondence Address: FARJAMI & FARJAMI LLP, 26522 LA ALAMEDA AVENUE, SUITE 360, MISSION VIEJO, CA, 92691, US

(21) Appl. No.: 12/228,476

(22) Filed: Aug. 13, 2008

Related U.S. Application Data
(60) Provisional application No. 60/964,552, filed on Aug. 13, 2007.

(51) Int. Cl. G05F 1/10; H01L 23/48

(52) U.S. Cl. 323/282; 257/691; 257/E23.01

(57) ABSTRACT

A multi-chip package that includes two power semiconductor devices coupled in a half-bridge arrangement and a driver for driving the two power semiconductor devices.

### RELATED APPLICATION

This application is based on and claims priority to U.S. Provisional Application Ser. No. 60/964,552, filed on Aug. 13, 2007, entitled Three Chip MCM on Discrete MLP with Copper Wire Bonds, to which a claim of priority is hereby made and the disclosure of which is incorporated by reference.

### BACKGROUND AND SUMMARY OF THE INVENTION

Multi-chip modules (MCMs) typically include a plurality of diverse elements disposed on one or more substrates or lead frame pads enclosed within a molded housing. The diverse elements are connected within the package to form an electronic circuit, e.g. as a half-bridge. A half-bridge arrangement includes two power semiconductor devices connected in series. A typical power semiconductor device is a power MOSFET, although other power semiconductor devices may be used.

It is an object of the present invention to have two semiconductor switches and a driver to operate the switches in one package to ensure low cost and to minimize power loss. A package according to the present invention includes two MOSFETs connectable in a half-bridge configuration between an input voltage and ground, and a driver chip to operate the MOSFETs.

Other features and advantages of the present invention will become apparent from the following description of the invention which refers to the accompanying drawings.

### BRIEF DESCRIPTION OF THE DRAWINGS

FIG. 1 is a typical application diagram of an MCM according to the present invention.

FIG. 2 is a simplified block diagram of an MCM according to the present invention.

FIG. 3 is an internal schematic of an MCM according to the present invention.

FIG. 4 depicts a top plan view of a package according to the present invention without specific illustration of the molded housing, the switches and the driver.

FIG. 5 depicts a top plan view of a package according to the present invention (the molded housing being rendered transparent).

FIG. 6 depicts a bottom plan view of a package according to the present invention.

FIG. 7 depicts a cross-sectional view along line 7-7 in FIG. 6 viewed in the direction of the arrows.

### DETAILED DESCRIPTION OF EMBODIMENTS OF THE INVENTION

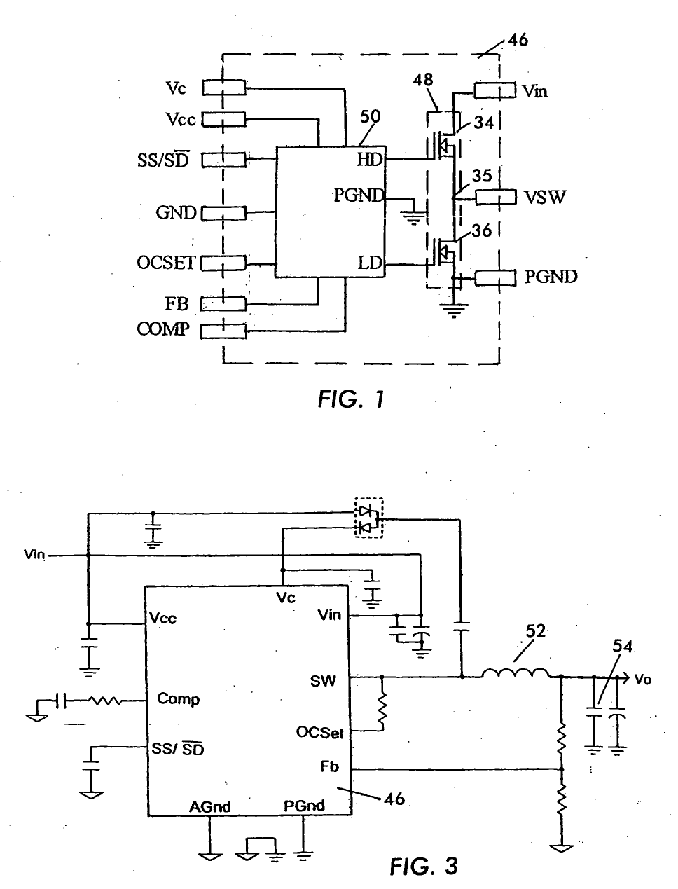

Referring to FIG. 1, a package 46 according to the present invention includes a power conversion stage 48, and a driver stage 50. Power conversion stage 48 includes a high side switch 34 and a low side switch 36. High side switch 34 and low side switch 36 are preferably N-channel power MOSFETs coupled to one another in a half-bridge configuration.

Specifically, the drain electrode of low side switch 36 is series connected with the source electrode of high side switch 34. The source electrode of the low side switch 36 is then connectable to ground PGND while the drain electrode of the high side switch is connectable to the voltage input Vin which is to be converted or regulated. The half-bridge configuration of the high side switch 34 and the low side switch 36 includes a switch node 35, which serves as the output of the conversion stage 48.

Driver stage 50 is preferably a driver integrated circuit (IC) which serves to provide a high drive signal HD to the gate electrode of high side switch 34 and low drive signal LD to the gate electrode of low side switch 36. The HD and LD serve to operate switches 34, 36, respectively.

In the preferred embodiment, a package according to the present invention is configured to be used in a buck converter. Thus, high side switch 34 may be configured as the control switch in the buck converter while low side switch 36 may be configured as the synchronous switch.

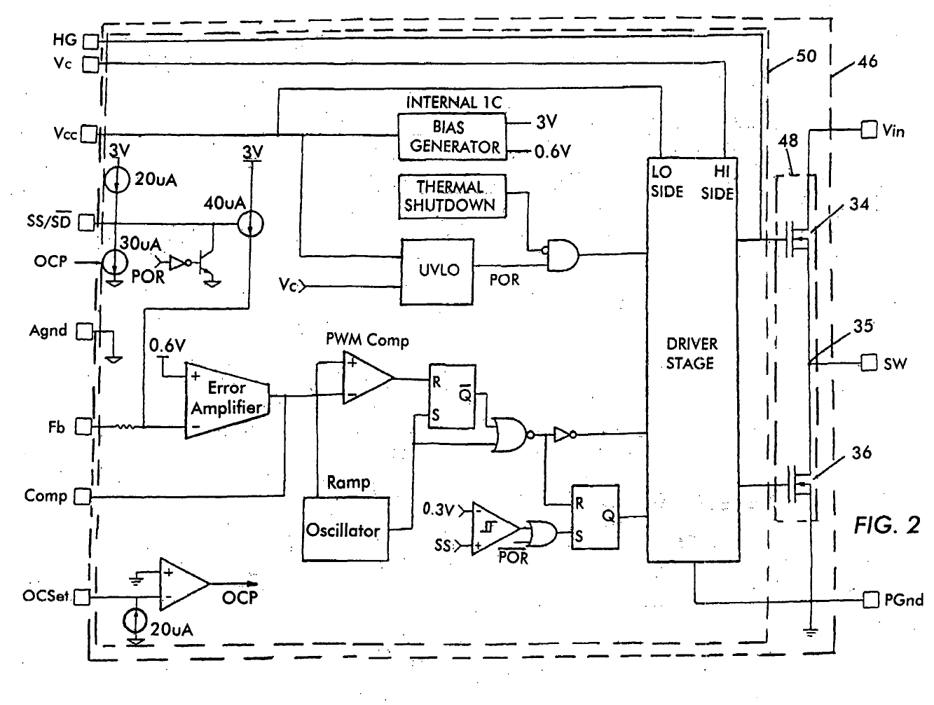

Referring now to FIG. 2 as well as FIG. 1, a package 46 according to the present invention would include a plurality of terminals for external communication. Table I below sets forth the function of each of the terminals of package 46:

TABLE I

| NAME | DESCRIPTION |
|---|---|
| Fb | Inverting input to the error amplifier. This terminal is |
| | connected directly to the output of the regulator via a |
| | resistor divider to set the output voltage and provide |
| | feedback to an error amplifier. |
| Comp | Output of error amplifier. An external resistor and |
| | capacitor network is typically connected from this |
| | terminal to ground to provide loop compensation. |
| AGnd | Signal ground for internal reference and control circuitry. |
| SS/Sd | Soft start/shutdown. This terminal provides user pro- |
| | grammable soft-start function. An external capacitor |
| | from this terminal to ground is typically connected to |
| | set the start up time of the output voltage. |
| OCSet | Current limit set point. A resistor from this terminal |
| | to SW terminal can set the current limit threshold. |
| V_{cc} | This terminal powers the internal IC as well as the low |
| | side driver. |
| PGnd | Power Ground. This terminal serves as a separated ground |
| | for the MOSFET drivers and is connectable to the system's |
| | power ground plane. |
| SW | Switch node. This terminal is connectable to the output |
| | inductor. |
| V_{IN} | Input voltage connection terminal. |
| HG | This terminal is connected to the high side MOSFET gate. |
| V_{c} | This terminal powers the high side driver and must be |
| | connected to a voltage higher than input voltage. |
| PGnd | Power Ground. This terminal serves as a separated ground |
| | for the MOSFET drivers and should be connected to the |
| | system's power ground plane. |

Referring now to FIG. 3, switch node SW of a package 46 according to the present invention can be series coupled to an output circuit that includes an inductor 52 and output capacitor 54. Inductor 52 and output capacitor 54 are series connected between switch node SW and ground. The point of connection between inductor 52 and output capacitor 54 can serve as the voltage output node Vo of a buck converter that uses a package 46 according to the present invention.

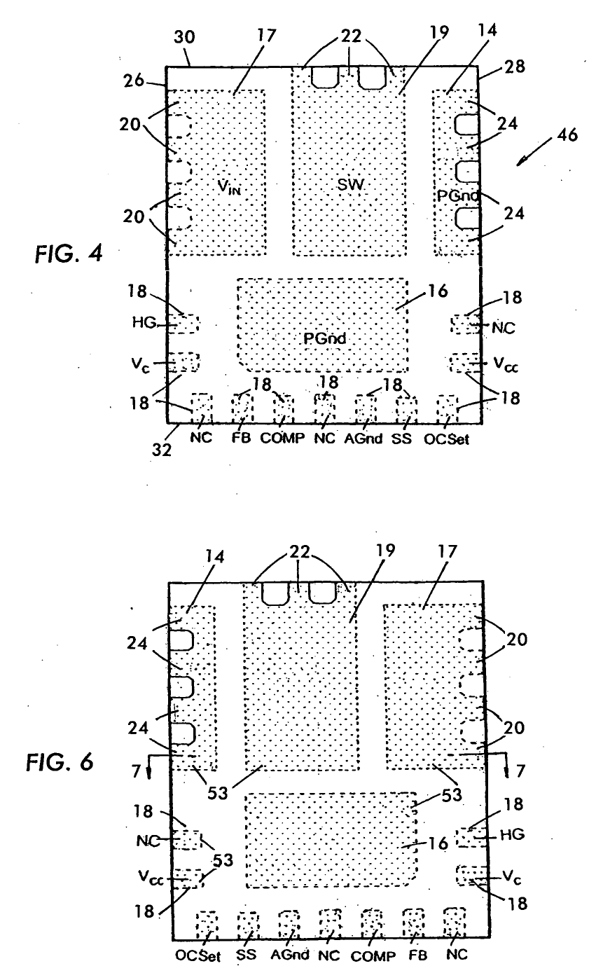

FIG. 4 illustrates the outline of a package according to the present invention. Note that for the convenience of the reader the molded housing of the package has been rendered transparent, and the driver, the power semiconductor devices and the wirebonds have been removed from view to better illustrate the lead frame configuration of the package. Thus, a package 46 according to the present invention includes a conductive pad 17 for receiving high side switch 34, a conductive pad 19 for receiving low side switch 36, a conductive pad 14 for connection to the ground, a conductive pad 16 for receiving driver die 38, and a plurality of leads 18 disposed opposite edges of pad 16. Pad 17 includes a plurality of integrated leads 20 extending from one edge thereof, pad 19 includes a plurality of integrated leads 22 extending from an edge thereof, and pad 14 includes a plurality of leads 24 extending from an edge thereof.

Integrated as used herein means that the leads and the pad form a unitary body. Note that the pads and leads form a lead frame, which may be preferably a micro lead frame.

According to one aspect of the present invention, leads 20 are disposed at one edge 26 of the package, leads 24 are disposed at another edge 28 of the package which is opposite and preferably generally parallel to edge 26, and leads 22 are disposed at an edge 30 of the package, which is transverse to (and preferably normal to) edges 30 and 28.

Note further that according to another aspect of the present invention, pads 17, 19, 14 are disposed such that each includes at least one edge thereof opposite and preferably generally parallel to an edge of another pad. In the preferred embodiment, as illustrated by FIG. 4, pad 19 is disposed between and spaced from pads 17 and 14, such that one edge of pad 19 is disposed opposite and generally parallel to an edge of pad 17, and pad 19 includes another edge opposite the one edge thereof opposite and generally parallel to the edge of pad 14.

Note that pad 16 includes one edge that is not opposite leads 18, but is opposite and generally parallel to at least one pad 19, or as illustrated, pads 19 and 17. Leads 18 are then disposed opposite the other receiving edges of pad 16. Note that some leads 18 can be disposed at edge 26, some leads 18 can be disposed at edge 28, and other leads 18 can be disposed at edge 32 of the package, which is opposite to and generally parallel to edge 30 of the package.

Leads 18, and pads 17, 19, 16 have also been related to respective functions set forth in TABLE I.

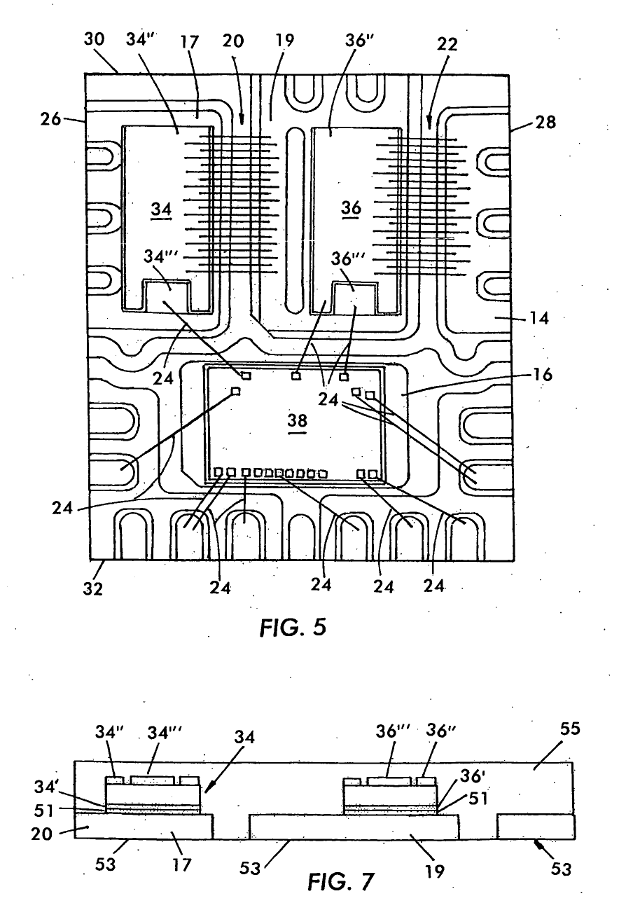

Referring now to FIGS. 5, 6 and 7, a package according to the preferred embodiment of the present invention includes high side switch 34, which can be a power MOSFET, low side switch 36, which can be a power MOSFET, and driver chip 38 for driving switches 34, 36. In the preferred embodiment, switches 34, 36 are connected in a half-bridge arrangement. Thus, drain electrode 34′ (see FIG. 7) of high side switch 34 is electrically and mechanically coupled to pad 17 using a conductive adhesive 51 (e.g. solder or conductive epoxy), drain electrode 36′ (see FIG. 7) of low side switch 36 is electrically and mechanically coupled to pad 19 using a conductive adhesive 51 (e.g. solder or conductive epoxy), source electrode 34″ of high side switch 34 is electrically connected to pad 19 using a plurality of wire bonds 40, and source electrode 36″ of switch 36 is electrically connected to pad 14 using a plurality of wire bonds 22. Note that wire bonds 20 and wire bonds 22 may be generally parallel and alternately sized. Thus, a pattern that includes a short wire bond 20 adjacent a long wire bond 20 is repeated. The same pattern is preferably implemented with wire bonds 22.

Driver chip 38 is coupled to gate electrodes 34′″, 36′″ of switches 34, 36 in order to operate the same, and is coupled to leads 18 in order to receive/send I/O (input/output) signals as appropriate. The preferred method of coupling the various functional pads of driver chip 38 to gate electrodes 34′″, 36′″ of switches 34, 36 and leads 18 is wire bonding (i.e. use of wire bonds 24) as illustrated.

According to an aspect of the present invention, copper wirebonds are used instead of gold wirebonds.

Referring specifically to FIGS. 6 and 7, a package according to the present invention includes a molded housing 55 (e.g. epoxy resin) which encapsulates switches 34, 36 and driver chip 38 and preferably all pads and leads in the package except for a connection surface 53 at the bottom of each pad 14, 16, 17, 19 and each of the leads 18, 20, 22, 24. Thus, in a package according to the present invention, connection surfaces 53 of pads 14, 16, 17, 19 or connection surfaces 53 of leads 18, 20, 22, 24 can be connected to respective external pads (of a circuit board, for example) using a conductive adhesive (e.g. solder or a conductive epoxy), whereby package 46 according to the present invention can be surface mounted. Note that molded housing 55 preferably defines the outer boundaries of a package according to the package. That is, leads 18, 20, 22, 24 do not extend beyond the outer boundary of molded housing 55. Note that driver chip 38 is at least mechanically coupled to pad 16 using a conductive adhesive (e.g. solder or a conductive epoxy) or a non-conductive adhesive.

In a package according to the present invention, the V_{C} powers the high-side of the driver. The V_{C} must be connected to a voltage higher than input voltage. The V_{CC} powers the low-side of the driver. In the preferred embodiment, the supply voltage can range between 4.5 and 14 V and the supply voltage for V_{C} can range between 10 and 28 V, while the output voltage can range between 0.6 and 12 V. Output current can range between 0 and 10 A. The device preferably operates at a frequency of 660 kHz.

In operation, an external capacitor can be connected from the soft start/shut down SS/SD terminal to allow user programmable soft-start function. Pulling this terminal below 0.3V can shut down the converter.

Furthermore, a resistor preferably sets the current limit threshold and a regulator may be connected via resistor divider to set the output voltage and provide feedback to the error amplifier.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed is:

1. A DC-DC converter package, comprising:
a converter circuit that includes a control switch that includes a drain electrode on one surface thereof, and a gate electrode and a source electrode on an opposite surface thereof, a synchronous switch that includes a drain electrode on one surface thereof, and a gate electrode and a source electrode on an opposite surface thereof, and a driver IC that includes a plurality of input/output electrodes;
a lead frame that includes a control switch conductive pad electrically and mechanically coupled to said drain electrode of said control switch, a synchronous switch conductive pad electrically an mechanically coupled to said drain electrode of said synchronous switch, an IC pad mechanically coupled to said driver IC, and a ground pad, said pads being spaced from one another;
a first plurality of wirebonds electrically connecting said ground pad to said source electrode of said synchronous switch;
a second plurality of wirebonds electrically connecting said source electrode of said control switch to said synchronous switch conductive pad;
at least a third wirebond electrically connecting a first input electrode to said gate electrode of said control switch;
at least a fourth wirebond electrically connecting a second input electrode to said gate electrode of said synchronous switch; and
a plurality of input/output leads each coupled electrically to a respective input/output electrode of said driver IC.

2. The DC-DC converter package of claim 1, wherein said ground pad includes a first plurality of unitarily integral leads, said control switch conductive pad includes a second plurality of unitarily integral leads, and said synchronous switch pad includes a third plurality of unitarily integral leads.

3. The DC-DC converter package of claim 2, wherein said first plurality of leads and said second plurality of leads terminate at first and second opposing edges of said package, while said third plurality of leads terminate at a third edge of said package, said third edge being transverse to said first and second edges.

4. The DC-DC converter package of claim 3, wherein at least a portion of said input/output leads are arranged at a fourth edge of said molded housing opposite said third edge of said package.

5. The DC-DC converter package of claim 1, wherein said input/output leads, said ground pad, said control switch pad, and said synchronous switch pad each includes a surface that is readied for connection to an external pad using a conductive adhesive.

6. The DC-DC converter package of claim 1, further comprising a molded housing encapsulating said control switch, said synchronous switch and said driver IC, and said molded housing defining the peripheral boundary of said DC-DC converter package.

7. The DC-DC converter package of claim 1, wherein said control switch and said synchronous switch are MOSFETs.

8. The DC-DC converter package of claim 1, wherein said converter circuit is the power stage of a buck converter.
